(19) United States
(12) Patent Application Publication
(10) Pub. No.: US 2007/0040266 A1
(43) Pub. Date: Feb. 22, 2007

(54) Heat-conducting packaging of electronic circuit units

(76) Inventors: Georg Stefan Dusberg, Dresden (DE); Werner Steinhogi, Munich (DE)

Correspondence Address: JENKINS, WILSON, TAYLOR & HUNT, P. A., 3100 TOWER BLVD, SUITE 1200, DURHAM, NC, 27707, US

(21) Appl. No.: 10/573,862

(22) PCT Filed: Sep. 14, 2004
(86) PCT No.: PCT/EP04/10262

§ 371 Date: Oct. 24, 2006

(30) Foreign Application Priority Data
Sep. 29, 2003 (DE) 103 45 157.9

(51) Int. Cl. H01L 23/34

(52) U.S. Cl. 257/706

(57) ABSTRACT

The invention relates to a heat-conducting coating of electronic circuit assemblies (102), comprising a coating agent (100), which encloses the electronic circuit assembly (102) and which is electrically insulating, with dispersed particles in the coating agent (100) which have a high thermal conductivity, whereby the particles dispersed in the coating agent (100) are embodied as nanoelements (101).

### TECHNICAL FIELD

The present invention relates generally to a heat-conducting packaging for heat dissipation from electronic circuit units, and relates in particular to a packaging device for packaging electronic circuit units with a packaging means, which surrounds the electronic circuit unit and which is electrically insulating, particles being dispersed in the packaging means, said particles having a high thermal conductivity, in order to dissipate heat from the electronic circuit unit toward an outer side of a package.

### BACKGROUND ART

Increasing miniaturization of electronic circuit units necessitates effecting efficient heat dissipation or efficient heat removal of the heat converted in the electronic circuit units toward the outer side of a housing or a package. An evolution of heat which arises during operation of integrated circuits which are operated on a silicon basis, by way of example, must therefore be effectively dissipated to the surroundings.

In this case, the corresponding heat flow passes through a series of materials having different thermal properties. Such materials comprise, in the case of a half power semiconductor, for example, the material silicon having a good thermal conductivity, a housing material made of an organic molding composition, which has a poor thermal conductivity, a copper plate or a metallic heat sink having a correspondingly good thermal conductivity; or in the case of a high-power CPU (central processing unit) the materials silicon having good thermal conductivity, adhesive having poor thermal conductivity and a heat distributor having good thermal conductivity, a further adhesive having poor thermal conductivity, a copper plate having good thermal conductivity and a heat sink having correspondingly good thermal conductivity.

Since such materials are arranged in series with regard to the heat flow, the element having the highest thermal resistance or the poorest thermal conductivity prescribes a measure of an upper limit of the thermal conductivity of the package of the electronic circuit unit. In the example mentioned above, the adhesive or the housing material or the packaging means of the electronic circuit unit is the element which has the highest thermal resistance.

Materials which are used as thermal conductors, adhesives, etc. are conventionally provided as organic plastics, such as, for example, epoxides, polyamides, etc. The thermal conductivity of such organic plastics is typically 0.2 W/mk. Consequently, one disadvantage of conventional packaging means is that their thermal conductivity has a very low value. Inter alia manner, the heat arising as a result of the increasing miniaturization of electronic circuit units can no longer be dissipated to a sufficient extent.

In order to eliminate this disadvantage, it has been proposed to increase the thermal conductivity of such organic plastics by introducing particles or clusters having a high thermal conductivity. In particular, it has been proposed to introduce silicon particles into the organic plastics, the composite materials arising then attaining thermal conductivities in the range around 1 W/mk (W=watt, m=meter, k=Kelvin).

FIG. 3 shows a conventional packaging device for packaging a power semiconductor by means of a composite material containing silicon particles. Situated within the packaging means is a metal as a base body, on which a silicon chip (Si chip) is fitted. Electrical connections which are electrically connected to the silicon chip via a connecting path serve for making electrical contact.

It is disadvantageous that the arrangement shown in FIG. 3 is not suitable for heat dissipation from power semiconductors in instances of relatively high evolution of heat, since the composite material with the introduced silicon particles has an excessively low thermal conductivity in the range of 1 W/mk.

It has furthermore been proposed to provide a heat distributor for electronic circuits, which comprises a matrix material into which carbon nanotubes are introduced as described in U.S. Pat. No. 6,407,922 B1. Such carbon nanotubes (CNT) are highly thermally conductive and act very effectively to transport a heat away from a circuit unit in one direction.

Furthermore, the publication “Biercuk et al.: Applied Physics Letters, vol. 80, No. 15, p. 2767 ff. (2002) Carbon nanotube composites for thermal management” discloses using carbon nanotube composites for heat conduction. One disadvantage of the disclosed devices for heat conduction is that the composites become electrically conductive with an increasing proportion of carbon nanotubes, which has the effect that the filler proportion is limited.

The filler proportion of carbon nanotubes in such heat conduction devices is disadvantageously 0.1% to 0.2%. This inexpediently has the effect that an increase in the thermal conductivity is restricted.

Consequently, it is an essential disadvantage of conventional methods and devices for packaging electronic circuit units that the packaging means do not have a sufficient thermal conductivity in conjunction with a required electrical insulation.

### SUMMARY OF THE INVENTION

Consequently, it is an object of the present invention to provide a packaging device for packaging electronic circuit units which has a sufficient thermal conductivity in conjunction with good insulation properties.

This object is achieved according to the invention by means of a packaging device having the features of claim 1. The object is furthermore achieved by means of a method specified in patent claim 15. Further refinements of the invention emerge from the subclaims.

One essential concept of the invention consists in utilizing a high thermal conductivity of nanoelements, for example carbon nanotubes, by dispersing them into a packaging means of a packaging device, a sufficient electrical insulation advantageously being provided by suppression of the electrical conductivity of the nanoelements.

A conductivity of the nanoelements or nanotubes is expediently provided by virtue of the fact that the nanoelements are provided with an electrically insulating sheathing layer. It is furthermore advantageous that the particles which are dispersed in the packaging means and are provided by the nanoelements having the high thermal conductivity are functionalized in such a way that electrical conduction properties of the nanoelements are suppressed.

Nanoelements formed as nanotubes have a particularly good thermal conductivity along their longitudinal axis, so that it is advantageously possible that the nanoelements forming the dispersed particles can be oriented in their longitudinal axis in parallel fashion at least in one heat flow which flows between the circuit unit and an outer side of the packaging device.

It is furthermore expedient to establish a length of the nanotubes to be significantly shorter than a thickness of the packaging means for the electronic circuit unit. Introducing nanoelements into the packaging means furthermore affords the advantage that the entire composite material becomes extremely hard, and thereby scratch-resistant, as a result of the admixture of nanotubes.

The packaging device according to the invention for packaging electronic circuit units essentially has:

a) a packaging means, which surrounds the electronic circuit unit and which is electrically insulating; and

b) particles dispersed in the packaging means, said particles having a high thermal conductivity, the particles dispersed in the packaging means being formed as nanoelements.

Furthermore, the method according to the invention for packaging electronic circuit units essentially has the following steps of:

a) providing a packaging means, which is electrically insulating;

b) dispersing particles having a high thermal conductivity in the packaging means; and

c) surrounding the electronic circuit unit with the packaging means in which the particles having the high thermal conductivity are dispersed, the particles dispersed in the packaging means being provided as nanoelements.

In accordance with one preferred development of the present invention, the nanoelements forming the dispersed particles are provided as nanotubes. It is furthermore expedient for the nanoelements forming the dispersed particles to be provided as silicon nanowires.

Preferably, the nanotubes are essentially constructed from carbon and thus formed as carbon nanotubes (CNT).

In accordance with a further preferred development of the present invention, the nanoelements forming the dispersed particles are provided with an electrically insulating sheathing layer. It is thus expedient that a high thermal conductivity is obtained in conjunction with suppression of the electrical conductivity of the dispersed particles. Furthermore, it is possible that the nanoelements forming the dispersed particles are functionalized in such a way that electrical conduction properties of the nanoelements are suppressed. Furthermore, it is advantageous that the nanoelements forming the dispersed particles are intrinsically doped in such a way that a metallic H system is eliminated.

In accordance with yet another preferred development of the present invention, the nanoelements forming the dispersed particles are provided as carbon nanotubes (CNT) and are intrinsically doped with nitrogen (N) and/or with boron (B) in such a way that the metallic H system is eliminated.

In accordance with yet another preferred development of the present invention, the nanoelements forming the dispersed particles are provided as hetero-nanotubes having a large band gap. Preferably, the nanoelements forming the dispersed particles are provided as hetero-nanotubes of this type containing boron nitride (BN), boron-carbon nitride (BCN) and/or vanadium pentoxide (V₂O₅).

In accordance with yet another preferred development of the present invention, the nanoelements forming the dispersed particles are oriented with a longitudinal axis parallel to at least one heat flow which flows between the circuit unit and an outer side of the packaging device.

Preferably, the longitudinal axes of the nanoelements forming the dispersed particles have extents which are significantly smaller than a thickness of the packaging means.

In accordance with yet another preferred development of the present invention, the electrically insulating sheathing layer, e.g. polymers, surfactants, oxides (SiO₂, Ta₂O₅), surrounding the nanoelements forming the dispersed particles has a layer thickness in a range of 5 nm to 50 nm (nanometers).

In accordance with yet another preferred development of the present invention, after surrounding the electronic circuit unit with the packaging means in which the particles having the high thermal conductivity are dispersed, the packaging means is cured. The curing is preferably provided at an elevated temperature.

In accordance with yet another preferred development of the present invention, a heat flow is transported from the circuit unit to an outer side of the packaging device via the packaging means in which the particles having the high thermal conductivity are dispersed, in order to cool the circuit unit.

In accordance with yet another preferred development of the present invention, a heat flow is transported from an outer side of the packaging device to the circuit unit via the packaging means in which the particles having the high thermal conductivity are dispersed, in order to heat the circuit unit.

Preferably, the nanoelements forming the dispersed particles are oriented with a longitudinal axis parallel to at least one heat flow which flows between the circuit unit and an outer side of the packaging device.

Exemplary embodiments of the invention are illustrated in the drawings and are explained in more detail in the description below.

### BRIEF DESCRIPTION OF THE DRAWINGS

FIG. 1 shows a packaging device in which a power semiconductor as an electronic circuit unit is packaged, in accordance with one preferred exemplary embodiment of the present invention;

FIG. 2 shows a packaging device arranged in a flip-chip housing, in accordance with a further preferred exemplary embodiment of the present invention; and

FIG. 3 shows a conventional packaging device for electronic circuit units.

### DETAILED DESCRIPTION OF THE INVENTION

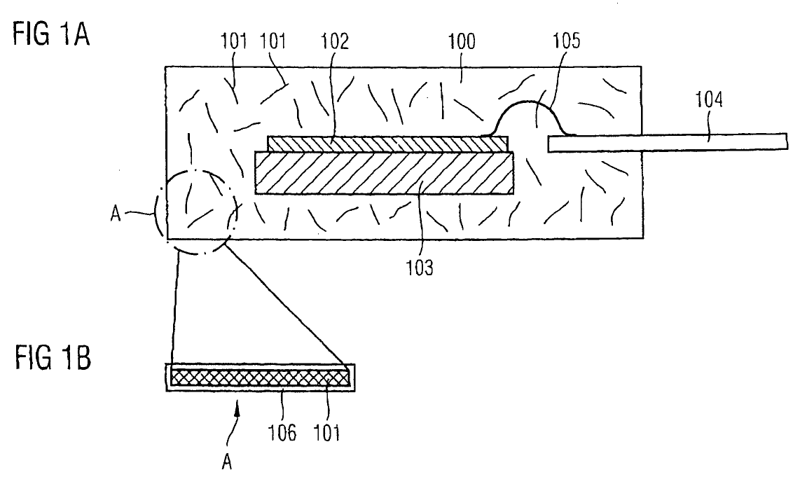

In the figures, identical reference symbols designate identical or functionally identical components or steps. The arrangement shown in FIG. 1 shows an electronic circuit unit 102, which is applied on a base body 103, packaged in the packaging device according to the invention. The circuit unit 102 and the base body 103 form a power semiconductor, for example, in such a way that the base body 103 is embodied from a metal on which a silicon chip (Si chip) is applied.

A connection unit 104 serves for making electrical contact with the circuit unit 102, said connection unit being connected to the circuit unit 102 via a connecting unit 105. A packaging means 100 surrounding the circuit unit 102, the base body 103, the connecting unit 105 and part of the connection unit 104 serves for packaging the power semiconductor formed from the circuit unit 102 and the base body 103. The outwardly projecting part of the connection unit 104 serves for making electrical contact with the circuit unit 102.

It should be pointed out that in order to maintain a functionality of the circuit unit 102, the packaging means 100 must have a high insulation capability. That is to say that the packaging means 100 must constitute an electrical insulator in order to prevent any voltage breakdowns that may occur in particular in the case of power semiconductors or power components.

According to the invention, particles are admixed with the packaging means 100, said particles being dispersed in the packaging means 100. FIG. 1 (a) shows the packaging device 100 with the electronic circuit unit 102 and the dispersed particles formed as nanoelements 101.

FIG. 1(b) shows a detail A from FIG. 1(a). It can be seen in FIG. 1(b) that a nanoelement 101 is provided with a sheathing layer 106, which is electrically insulating. This makes it possible to combine the very good heat conduction properties with electrical insulation. Such an insulating enveloping layer or sheathing layer 106 has a layer thickness preferably in the range of 5 to 50 nanometers (nm), and, even more preferably, the layer thickness is 25 nm. In the case where the sheathing layer 106 has a thickness of 25 nm, the minimum distance between the nanoelements 101, which are preferably formed from carbon nanotubes, is 50 nm.

The minimum distance between the carbon nanotubes suffices to ensure outstanding electrical insulation of the packaging means. In the case of carbon nanotubes having typical diameters of 10 nm, the maximum geometrically possible volume proportion for such a configuration is 3% and is thus significantly higher than the proportion of carbon nanotubes in conventional packaging means, which, as explained above, is 0.2% to 0.3%. A particular advantage resides in the extremely high thermal conductivity of carbon nanotubes, which is of the order of magnitude of 6 000 W/mk in the axial direction. With a reduction of the layer thickness of the sheathing layer 106 to 5 nm, which is suitable in some cases in order ensure good electrical insulation, this results in a volume proportion of the carbon nanotubes of the order of magnitude of 25%.

It should be pointed out that a distance between the carbon nanotubes only has to be large enough to prevent tunneling currents from flowing.

Furthermore, it is possible for the nanoelements forming the dispersed particles to be functionalized in such a way that an electrical conduction behavior of the nanoelements is suppressed. This is achieved for example by “functionalization” of carbon nanotubes. It should be pointed out that the insulation of carbon nanotubes as shown in FIG. 1(b) in accordance with a preferred exemplary embodiment of the present invention only represents one possibility for electrically insulating the nanoelements. In the case of a functionalization (not shown in the figures) of carbon nanotubes, the high thermal conductivity of the phenonic system, that is to say of the thermally excited oscillations of the lattice atoms, is maintained since the thermal conductivity is largely independent of the electrical conductivity. The electrical conductivity of the carbon nanotubes is based on the fact that the conduction electrons form a delocalized π electron system.

Such independence between the electrical conductivity and the thermal conductivity is also provided for example in a diamond material. Diamond material has a very high thermal conductivity borne by the phenonic system of the diamond material, while the diamond material is an excellent electrical insulator. In the case of carbon nanotubes, it is possible to modify the electronic system by means of a controlled chemical functionalization, that is to say a chemical attack, for example using halogens, sulfur and/or oxygen groups, in such a way that the metallic character of the carbon nanotubes is suppressed. The bond relationships—which are critical for the phenonic system—between the carbon atoms of the carbon nanotubes are influenced only little by such functionalization.

This has the effect that the heat-conducting properties are retained, while at the same time an electrical conductivity is eliminated.

In accordance with a further preferred embodiment of the present invention, which is not shown in the figures, it is possible for the nanoelements 102 forming the dispersed particles to be intrinsically doped in such a way that a metallic n system is eliminated. Such intrinsic doping of carbon nanotubes is effected for example using nitrogen or boron, whereby the metallic H system is destroyed.

It should be pointed out that such functionalization and/or intrinsic doping is known to average persons skilled in the art, as disclosed for example in the publications “Seifert et al.: Applied Physics Letters, vol. 77, p. 1313 ff., (2000): Molecular wires, solenoids, and capacitors by sidewall functionalization of carbon nanotubes” and “Goldberg et al.: Chemical Physics Letters, vol. 308, p. 307 ff. (1999): Single-walled B-doped carbon, B/N-doped carbon and BN nanotubes synthesized from single-walled carbon nanotubes through substitution reaction”.

In accordance with a further preferred embodiment, the nanoelements 102 forming the dispersed particles are provided as hetero-nanotubes, in such a way that a large band gap arises. Such hetero-nanotubes are formed for example from a material BN (boron nitride), BCN (boron-carbon nitride) and/or V₂O₅ (vanadium pentoxide) with large energy gaps in each case.

Thus, the energy gap for boron nitride (BN) is 5 eV, for example, such that the, band gap leads to an electrically insulating behavior. It should be pointed out that the band gap in the case of silicon is only <1 eV.

With regard to the thermal conductivity, the hetero-nanotubes have the same spatial arrangement as the atoms of known carbon nanotubes. Therefore, the hetero-nanotubes exhibit a similar structure of the phenonic system to that in the case of the carbon nanotubes, such that an excellent thermal conductivity of the hetero-nanotubes is provided.

Methods for producing boron nitride nanotubes, for example are known to average persons skilled in the art, as disclosed in the publication “Fuentes et al.: Physical Review B, vol. 67, p. 035429 ff (2003): Electronic structure of multiwall boron nitride nanotubes”.

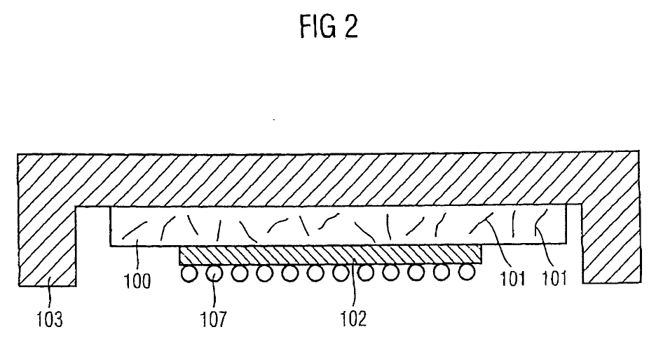

FIG. 2 shows a further preferred exemplary embodiment in accordance with the present invention. A base body 103 is arranged as a holding element, forming a support of a flip-chip housing. The base body 103 is embodied from a metal, for example, to which the packaging means 100 containing the nanoelements 101 is applied.

In the arrangement shown in FIG. 2, an integrated circuit unit is arranged on a silicon chip as the circuit unit 102, which is provided with circuit unit connection elements 107. The packaging means 100, which is provided with nanoelements 101 according to the invention, serves for insulating the circuit unit 102 form the base body 103. As already mentioned above with reference to FIG. 1, the nanoelements 101 constitute an excellent thermal conductivity of the packaging means, such that heat flows can be transferred efficiently between the base body 103 and the circuit unit 102.

According to the invention, an electrical conductivity of the nanoelements is suppressed in such a way that the packaging means 100, which, in the exemplary embodiment of the present invention as shown in FIG. 2, functions as a connecting means between the base body 103 and the circuit unit 102, has a sufficient electrical insulation property.

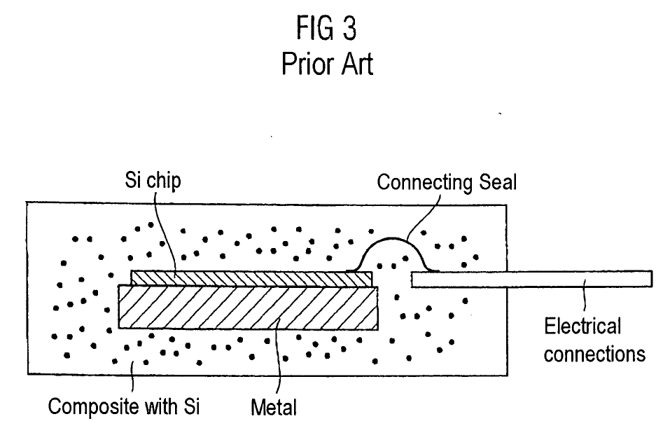

With regard to the conventional packaging device illustrated in FIG. 3, reference is made to the introduction to the description.

Although the present invention has been described above on the basis of preferred exemplary embodiments, it is not restricted thereto, but rather can be modified in diverse ways.

Moreover, the invention is not restricted to the application possibilities mentioned.

### LIST OF REFERENCE SYMBOLS

In the figures, identical reference symbols designate identical or functionally identical components or steps.

100 Packaging means

101 Nanoelements

102 Circuit unit

103 Base body

104 Connection unit

105 Connecting unit

106 Sheathing layer

107 Circuit unit connection elements

1. A packaging device for packaging electronic circuit units, comprising:
a) a packaging means, which surrounds the electronic circuit unit (102) and which is electrically insulating; and
b) particles dispersed in the packaging means, said particles having a high thermal conductivity, wherein
c) the particles dispersed in the packaging means are formed as nanoelements.

2. The device as claimed in claim 1, wherein the nanoelements forming the dispersed particles are provided as nanotubes.

3. The device as claimed in claim 1, wherein the nanoelements forming the dispersed particles are provided as silicon nanowires.

4. The device as claimed in claim 2, wherein the nanotubes are essentially constructed from carbon and formed as carbon nanotubes.

5. The device as claimed in claim 1, wherein the nanoelements forming the dispersed particles are provided with an electrically insulating sheathing layer.

6. The device as claimed in claim 1, wherein the nanoelements forming the dispersed particles are functionalized in such a way that electrical conduction properties of the nanoelements are suppressed.

7. The device as claimed in claim 1, wherein the nanoelements forming the dispersed particles are intrinsically doped in such a way that a metallic Π system is eliminated.

8. The device as claimed in claim 7, wherein the nanoelements forming the dispersed particles are provided as carbon nanotubes and are intrinsically doped with nitrogen and/or with boron in such a way that the metallic Π system is eliminated.

9. The device as claimed in claim 1, wherein the nanoelements forming the dispersed particles are provided as hetero-nanotubes having a large band gap.

10. The device as claimed in claim 9, wherein the nanoelements forming the dispersed particles are provided as hetero-nanotubes containing boron nitride, boron-carbon nitride and/or vanadium pentoxide.

11. The device as claimed in claim 1, wherein the nanoelements forming the dispersed particles are oriented with a longitudinal axis parallel to at least one heat flow which flows between the circuit unit and an outer side of the packaging device.

12. The device as claimed in claim 1, wherein the nanoelements forming the dispersed particles have in their longitudinal axes extents which are significantly smaller than a thickness of the packaging means.

13. The device as claimed in claim 5, wherein the electrically insulating sheathing layer surrounding the nanoelements forming the dispersed particles has a layer thickness in a range of 20 nm to 30 nm.

14. An electrical insulator comprising a packaging device as claimed in claim 1.

15. A method for packaging electronic circuit units, comprising the steps of:
a) providing a packaging means, which is electrically insulating;
b) dispersing particles having a high thermal conductivity in the packaging means; and
c) surrounding the electronic circuit unit with the packaging means in which the particles having the high thermal conductivity are dispersed, wherein
d) dispersing the particles dispersed in the packaging means are provided as nanoelements.

16. The method as claimed in claim 15, wherein after surrounding the electronic circuit unit with the packaging means in which the particles having the high thermal conductivity are dispersed, the packaging means is cured.

17. The method as claimed in claim 15, wherein a heat flow is transported from the circuit unit to an outer side of the packaging device via the packaging means in which the particles having the high thermal conductivity are dispersed, in order to cool the circuit unit.

18. The method as claimed in claim 15, wherein a heat flow is transported from an outer side of the packaging device to the circuit unit via the packaging means in which the particles having the high thermal conductivity are dispersed, in order to heat the circuit unit.

19. The method as claimed in claim 15, wherein the nanoelements forming the dispersed particles are provided as nanotubes.

20. The method as claimed in claim 15, wherein the nanoelements forming the dispersed particles are provided as silicon nanowires.

21. The method as claimed in claim 15, characterized in that the nanotubes are essentially produced from carbon in the form of carbon nanotubes.

22. The method as claimed in claim 15, wherein the nanoelements forming the dispersed particles are coated with an electrically insulating sheathing layer.

23. The method as claimed in claim 15, wherein the nanoelements forming the dispersed particles are functionalized in such a way that electrical conduction properties of the nanoelements are suppressed.

24. The method as claimed in claim 15, wherein the nanoelements forming the dispersed particles are intrinsically doped in such a way that a metallic Π system is eliminated.

25. The method as claimed in claim 24, wherein the nanoelements forming the dispersed particles are provided as carbon nanotubes and are intrinsically doped with nitrogen and/or with boron in such a way that the metallic Π system is eliminated.

26. The method as claimed in claim 15, wherein the nanoelements forming the dispersed particles are provided as hetero-nanotubes having a large band gap.

27. The method as claimed in claim 26, wherein the nanoelements forming the dispersed particles are provided as hetero-nanotubes containing boron nitride, boron-carbon nitride and/or vanadium pentoxide.

28. The method as claimed in claim 15, wherein the nanoelements forming the dispersed particles are oriented with a longitudinal axis parallel to at least one heat flow which flows between the circuit unit and an outer side of the packaging device.

29. The method as claimed in claim 15, wherein the nanoelements forming the dispersed particles have in their longitudinal axes extents which are significantly smaller than a thickness of the packaging means.
